(19) United States
(12) Patent Application Publication
(10) Pub. No.: US 2020/0294876 A1
(43) Pub. Date: Sep. 17, 2020

(54) ELECTRONIC DEVICE HAVING PRODUCT INFORMATION AND METHOD FOR READING THE PRODUCT INFORMATION

(71) Applicant: TDK Corporation, Tokyo (JP)

(72) Inventor: Yongfu CAI, Tokyo (JP)

(21) Appl. No.: 16/351,769

(22) Filed: Mar. 13, 2019

(51) Int. Cl. H01L 23/29; H01L 43/02; H01L 23/552; G06K 7/10

(52) U.S. Cl. CPC H01L 23/29; G06K 7/10366; H01L 23/552; H01L 43/02

(57) ABSTRACT

An electronic device has a function part 3, a first product information part 6 made of metal, a molded resin 11 that covers the function part 3 and the first product information part 6, and a barrier layer 8 interposed between the first product information part 6 and the molded resin 11.

### BACKGROUND OF THE INVENTION

### 1. Technical Field

The present invention relates to an electronic device having a product information part and a method for reading the product information and, more particularly, to a configuration for safeguarding a product information part of an electronic device.

### 2. Related Art

In electronic devices, product information of the electronic device is formed for the purpose of post-manufacturing examination of causes of defects and the like. JP Laid-Open Patent Application No. H05-96895 discloses an IC card in which an IC module is incorporated. The IC module has a substrate on which an IC chip is mounted, and on the substrate, a product information part is formed that displays product information such as the lot number, version number and the like of the IC module. The product information part is formed of a material through which x-rays cannot penetrate. Specifically, the product information part is formed by etching a conductive material. The IC module is covered by molded resin for protection. When confirming the product information, the IC card is irradiated with x-rays.

### OVERVIEW OF THE INVENTION

When forming the product information part of a metal material, it is necessary to protect the product information part from corrosion. The molded resin prevents the product information part from being directly exposed to the outside environment and protects the product information part. However, molded resins may contain components that corrode metal, such as halogen elements. Consequently, if the product information part is in prolonged contact with the molded resin, the product information part corrodes, and identification of the product information with x-rays may become impossible.

It is an object of the present invention to provide an electronic device in which corrosion of the product information part is unlikely to occur.

The electronic device of the present invention has a function part, a first product information part made of metal, molded resin that covers the function part and the first product information part, and a barrier layer interposed between the first product information part and the molded resin.

With this configuration, it is possible to prevent the resin from directly contacting the first product information part, so corrosion of the first product information part by the resin is unlikely to occur. Accordingly, with the present invention, it is possible to provide an electronic device in which corrosion of the product information part is unlikely to occur.

The above-described and other objectives, characteristics and advantages of the present application are described in detail below with reference to the attached drawings that exemplify the present application.

### BRIEF DESCRIPTION OF THE DRAWINGS

FIG. 1 is a side cross-sectional view of a magnetic sensor according to a first embodiment of the present invention.

FIG. 2 is a partial enlarged view of FIG. 1.

FIGS. 3A and 3B are plan views along line A-A in FIG. 1.

FIGS. 4A and 4B are partial side cross-sectional views showing a variation of the magnetic sensor according to the first embodiment.

FIGS. 5A-5C are summary diagrams showing processes for forming a passivation film for the magnetic sensor shown in FIG. 1.

FIGS. 6A and 6B are side cross-sectional views of a magnetic sensor according to a second embodiment of the present invention.

FIGS. 7A and 7B are side cross-sectional views of a magnetic sensor according to a third embodiment of the present invention.

FIGS. 8A and 8B are side cross-sectional views of a magnetic sensor according to a fourth embodiment of the present invention.

FIG. 9A is a side cross-sectional view of a magnetic sensor according to a fifth embodiment of the present invention.

FIG. 9B is a plan view along line A-A in FIG. 9A.

### DETAILED DESCRIPTION OF THE INVENTION

Below, some embodiments of the present invention are described. The embodiments described below relate to a magnetic sensor, but the present invention can also be applied to other electronic devices having product information parts. The product information is primarily ID information such as the product name, manufacturing number, lot number and the like of that product, but may also be the manufacturing date, manufacturing plant, manufacturing country or the like and may also be various kinds of identification information necessary in manufacturing procedures, such as wafer identification number or the like. In the description below and the drawings, the direction in which the silicon substrate 4, the function part 3 and the barrier layer 8 are layered, or the direction orthogonal to the information formation surface 6A of the first product information part 6, is called the Z direction.

### First Embodiment

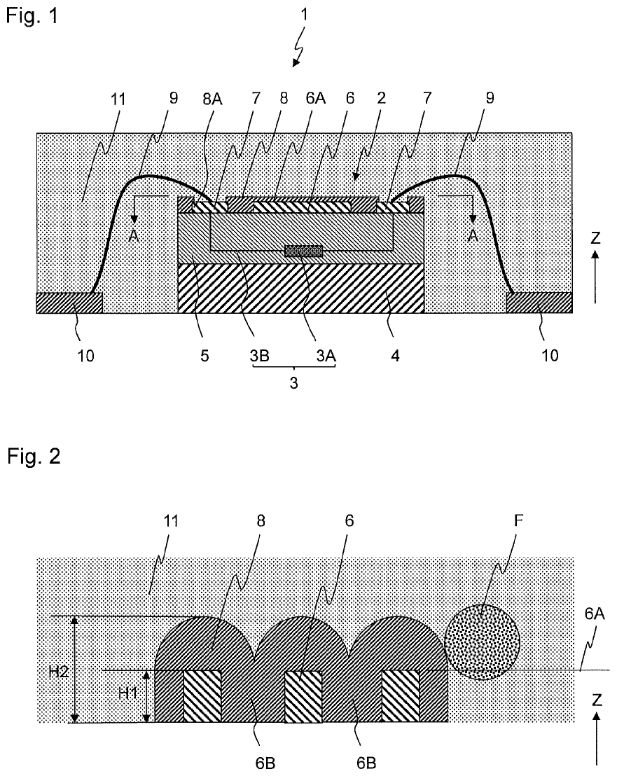

FIG. 1 shows a side cross-sectional view of a magnetic sensor 1 according to a first embodiment of the present invention. FIG. 2 shows an enlarged view of the vicinity of a first product information part 6. The magnetic sensor 1 includes a sensor unit 2 provided with a silicon substrate 4 and a function part 3 formed on the silicon substrate 4. The sensor unit 2 is covered by molded resin 11 except for the bottom part of the silicon substrate 4. The molded resin 11 includes a resin material such as epoxy resin or the like, and a filler made from inorganic materials such as silica or the like. The resin material in general has a high coefficient of thermal expansion, but the coefficient of thermal expansion of the filler is small. Through this, the coefficient of thermal expansion of the entire molded resin 11 is suppressed, and excessive stress is less likely to applied to the function part 3.

The function part 3 means the part necessary for accomplishing the inherent functions of the magnetic sensor 1, and, for example, includes a magnetic field detection element 3A, a wiring layer 3B connected to the magnetic field detection element 3A, and the like. As the magnetic field detection element 3A, a Hall's element, a magnetoresistive element such as, AMR element, TMR element, GMR element or the like can be preferably used. The function part 3 is covered by an insulating film 5 such as Al2O3 or the like. On the top surface of the insulating film 5, a first product information part 6 made of metal is formed. The first product information part 6 is made of a metal layer formed in a shape such that the identification information is identifiable or visible. The top surface of the first product information part 6 is an information formation surface 6A on which the identification information is formed. The first product information part 6 can be formed of an arbitrary material with low x-ray permeability, and, in particular, is preferably formed of a metal with lower x-ray permeability per unit thickness than Al. As this kind of metal, metals with higher specific gravity than Al can be cited, such as Au, W or the like. In this embodiment, the first product information part 6 is formed of Au in consideration of the manufacturing process. The thickness H1 of the first product information part 6 is preferably about 1˜10 μm to ensure visibility at the time of x-ray irradiation.

Electrode layers 7 connected to the wiring layer 3B are formed on the top surface of the insulating film 5 opposite to the silicon substrate 4. The electrode layers 7 are made of the same metal (Au) as the first product information part 6 and is positioned at the same distance as the first product information part 6 from the silicon substrate 4. In addition, the thickness of the electrode layers 7 is the same as the thickness of the first product information part 6. Consequently, the electrode layers 7 and the first product information part 6 can be formed together in the same process. For example, the resist is provided with openings, which are at the portion where the electrode layers 7 are formed and the portion where the first product information part 6 is formed, and the electrode layers 7 and the first product information part 6 can be formed by plating using resist as a mask.

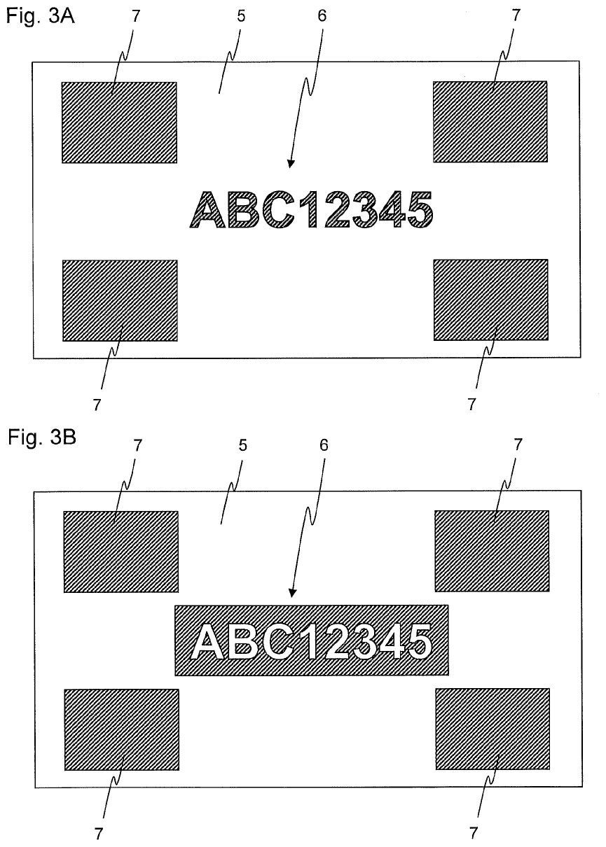

FIGS. 3A and 3B show plan views along line A-A in FIG. 1, that is, the information formation surface 6A of the first product information part 6. The first product information part 6 includes a three-dimensional pattern showing at least one of characters, symbols and figures. The characters include at least one of numbers and alphabetic letters but may also include other characters such as Greek letters. The figures include circles, quadrangles and lines but may also include a set of dots such as a QR code, or the like, or a set of lines such as a bar code, or the like. The section recognized as the identification information may be positive or negative. In FIGS. 3A and 3B, the hatched portions indicate the Au layer. FIG. 3A shows the positive-type identification information and, for example, the three lines configuring the letter “A” are formed by protrusions. FIG. 3B shows negative-type identification information and, for example, the three lines configuring the letter “A” are formed by indentations and penetration parts provided in the Au layer. The three-dimensional pattern can be formed by a commonly known method such as sputtering of the metal layer.

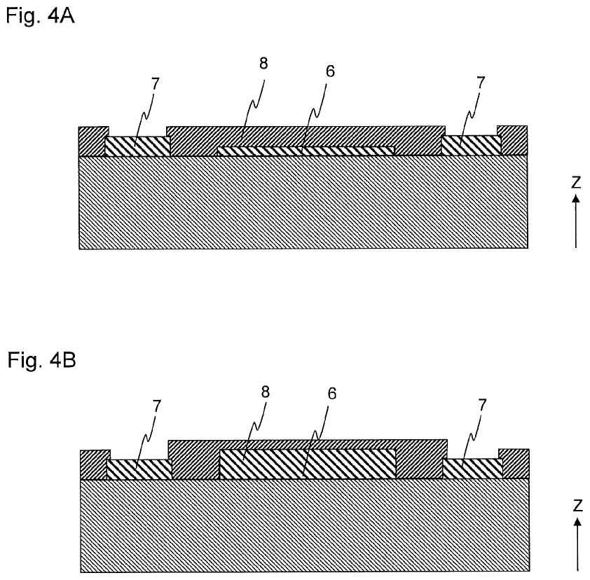

The thickness of the first product information part 6 and the thickness of the electrode layers 7 (dimension in the Z direction) may mutually differ. Referring to FIG. 4A, the first product information part 6 is thinner than the electrode layers 7. In this embodiment, it is easy to secure a sufficient thickness of a passivation film 8 so that pinholes caused by unevenness of the first product information part 6 are unlikely to occur in the passivation film 8. Consequently, the efficacy of protecting the first product information part 6 from the molded resin 11 is further improved. Referring to FIG. 4B, the first product information part 6 is thicker than the electrode layers 7. In this embodiment, it is easy to increase the height of the protrusion and the depth of the indentations or penetration parts of the first product information part 6, so the contrast of the identification information when imaged by x-rays is improved.

The first product information part 6 is covered by the passivation film 8 made of Sift, SiN, PI or the like. The passivation film 8 configures the barrier layer for the first product information part 6. As shown in FIG. 2, the passivation film 8 also fills in gaps 6B in the first product information part 6. The gaps 6B in the first product information part 6 are spaces between adjacent letters or adjacent numbers, or spaces inside letters or numbers, when the product information is the positive-type, and are the indentations and penetrating holes configuring the letters or numbers in the case of the negative-type. The passivation film 8 has an opening 8A that exposes the electrode layers 7, at a position facing the electrode layers 7. The electrode layers 7 are electrically connected to an external electrode terminal 10 by a wire 9. The resin material of the molded resin 11 in some cases contains halogen elements such as Cl, and halogen elements can cause corrosion of metal. In this embodiment, the first product information part 6 is positioned between the function part 3 and the passivation film 8. In other words, the passivation film 8 is interposed between the first product information part 6 and the molded resin 11. As a result, direct contact with the resin material by the first product information part 6 is prevented, so corrosion of the first product information part 6 is unlikely to occur. In addition, before the resin hardens, the filler F flowing inside the resin contacts with the passivation film 8 and can damage the passivation film 8 (see FIG. 2). To ensure the soundness of the passivation film 8, the film thickness H2 of the passivation film 8 is preferably 0.5 μm or greater.

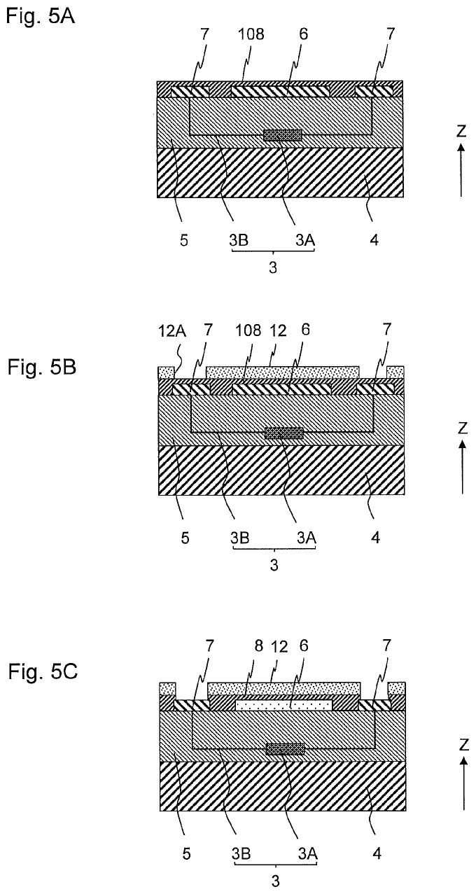

The passivation film 8 can be formed by a method using resist and photolithography. First, as shown in FIG. 5A, the function part 3 and the insulating film 5 are formed on the silicon substrate 4, and the first product information part 6 and the electrode layers 7 are formed through plating or sputtering on top of the insulating film 5. As described above, since the first product information part 6 and the electrode layers 7 are made of Au, they can be simultaneously formed in the same process. Furthermore, the first product information part 6 and the electrode layers 7 are covered by an inorganic film 108 that becomes the passivation film 8. The top surface of the inorganic film 108 is flattened through polishing. Next, as shown in FIG. 5B, a resist 12 is formed on top of the inorganic film 108, and an opening 12A is formed through photolithography at the position in the resist 12 where the electrode layers 7 are formed. Next, as shown in FIG. 5C, the inorganic film 108 above the electrode layers 7 are removed and the electrode layers 7 are exposed through milling via the opening 12A in the resist 12. Through this, the passivation film 8 covering the first product information part 6 and exposing the electrode layers 7 are formed, and the sensor unit 2 is finished. Furthermore, the magnetic sensor 1 is formed by electrically connecting the electrode layers 7 to the external electrode terminal 10 by the wire 9 and covering the sensor unit 2 with molded resin 11.

When a problem occurs in the magnetic sensor 1, x-rays are irradiated from outside the molded resin 11, and the product information included in the first product information part 6 is read. The x-rays are irradiated on the magnetic sensor 1 in the Z direction, and the captured images are recorded in a light-receiving part (photosensitive part) provided on the opposite side of the magnetic sensor from the x-ray irradiation device. When the product information is the positive type, the product information is displayed as black on the image, and when the product information is the negative type, the product information is displayed as gray on the image. The manufacturing number and manufacturing lot included in the product information is beneficial information for investigating causes and planning countermeasures. Normally, the magnetic sensor is used as one part of another product, so it may be difficult to remove the magnetic sensor for inspection. In addition, it may also be difficult to remove the molded resin covering the magnetic sensor. Conventionally, when product information is recorded inside a magnetic sensor, direct verification of the product information was accomplished by removing the magnetic sensor and the molded resin. However, this may damage the function part or change the stress state applied to the function part, and the cause may not be properly determined. In this embodiment, it is possible to read the product information by irradiating x-rays from outside, so the above-described problems do not arise.

### Second Embodiment

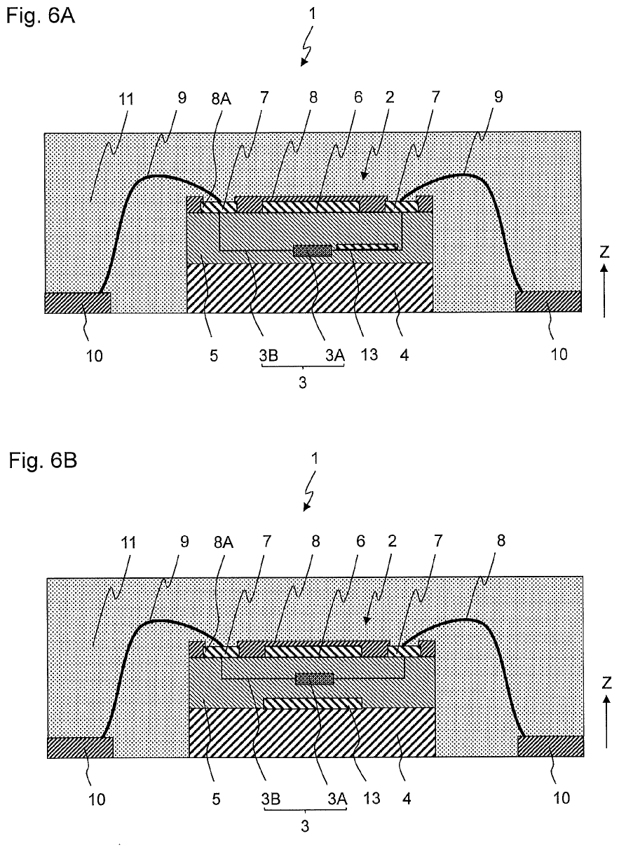

FIG. 6A shows a side cross-sectional view of the magnetic sensor 1 according to a second embodiment of the present invention. This embodiment is the same as the first embodiment except that, in addition to the first product information part 6, a second product information part 13 is also provided. The second product information part 13 is provided between the silicon substrate 4 and the first product information part 6, and the insulating film 5 covers the function part 3 and the second product information part 13. That is, a second barrier layer for the second product information part 13 is formed by the insulating film 5. The second product information part 13 can have the same configuration as the first product information part 6. The second product information part 13 is preferably formed of the same metal layer as the wiring layer 3B and provided at a position equidistant from the silicon substrate 4 with the wiring layer 3B. Through this, the wiring layer 3B and the second product information part 13 are arranged at the same level with respect to the silicon substrate 4, and the wiring layer 3B and the second product information part 13 can be formed in the same process. However, the position where the second product information part 13 is provided is not limited as long as this position is inside the insulating film 5. FIG. 6B shows a variation of this embodiment. The second product information part 13 is provided on the silicon substrate 4, and the insulating film 5 covers the function part 3 and the second product information part 13.

Product information the second product information part 13 has is not particularly limited. However, the second product information part 13 is formed at an earlier stage of the manufacturing process than the first product information part 6, so there are cases in which the second product information part 13 is more beneficial than the first product information part 6. For example, when confirming wafer identification information and the like midway through the manufacturing procedure, even at early stages of the manufacturing procedure, it is possible to refer to the second product information part 13. In particular, in the example shown in FIG. 6B, the product information is formed at the earliest stage, so it is most beneficial for production management. To mutually identify the first product information part 6 and the second product information part 13, preferably, the first product information part 6 and the second product information part 13 are provided in positions that do not mutually overlap when viewed from the Z direction. X-rays are irradiated to penetrate the magnetic sensor 1, so the accuracy of the x-ray image is not heavily influenced by the second product information part 13 in the Z direction position.

### Third Embodiment

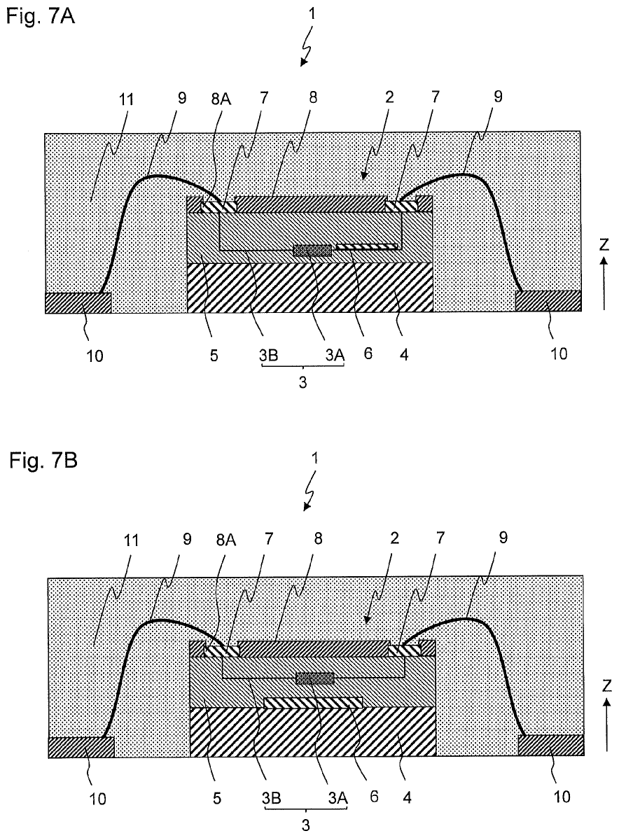

FIG. 7A is a side cross-sectional view of the magnetic sensor 1 according to a third embodiment of the present invention. This embodiment is the same as the first embodiment, except that the first product information part 6 is covered by the insulating film 5 that covers the function part 3. In this embodiment, the barrier layer is configured by the insulating film 5. Similar to the second embodiment, the first product information part 6 is preferably formed by the same metal layer as the wiring layer 3B and provided at a position equidistant from the silicon substrate 4 with the wiring layer 3B. Through this, the wiring layer 3B and the first product information part 6 are arranged at the same level relative to the silicon substrate 4, and the wiring layer 3B and the first product information part 6 can be formed in the same process. Although omitted from the drawing, an element such as a coil or the like may be provided between the first product information part 6 and the passivation film 8. FIG. 7B shows a variation of this embodiment. The first product information part 6 is provided on the silicon substrate 4, and the insulating film 5 covers the function part 3 and the first product information part 6. This embodiment, like the second embodiment, is beneficial for manufacturing management because the first product information part 6 is formed at an early stage of the manufacturing process compared to the first embodiment.

### Fourth Embodiment

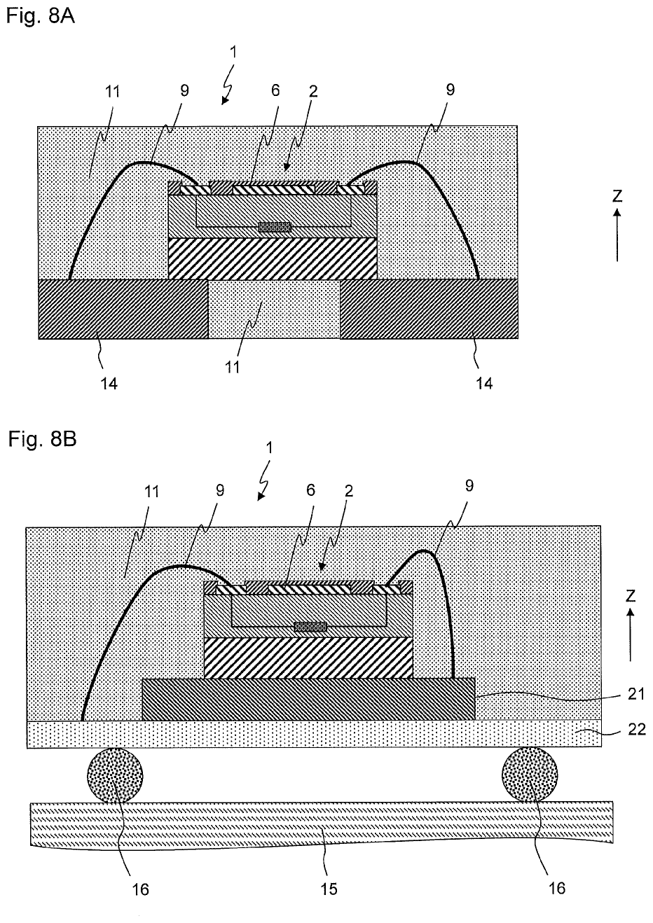

FIG. 8A shows a side cross-sectional view of the magnetic sensor 1 according to a fourth embodiment of the present invention. This embodiment is the same as the first embodiment except that the sensor unit 2 is connected to a lead frame 14. The sensor unit 2 is attached to the lead frame 14 positioned diagonally downward. The configuration of the sensor unit 2 is not limited to the first embodiment and may have the configuration of the second or third embodiment. The lead frame 14 has a relatively thick metal element such as a metal layer, and thus, when the sensor unit 2 is irradiated with x-rays, the first product information part 6 may overlap with the metal element of the lead frame 14, and the product information may not be read. Consequently, in this embodiment, the mutual positions are adjusted so that the lead frame 14 does not overlap with the first product information part 6 when viewed from the Z direction. Beside the lead frame 14, metal elements that potentially interfere with the first product information part 6 and prevent reading of the product information may be provided inside the sensor unit 2. Such metal elements also preferably do not overlap with the first product information part 6 when viewed from the Z direction.

FIG. 8B shows a variation of this embodiment. In this variation, the sensor unit 2 is connected to a circuit 21 such as an application specific integrated circuit (ASIC) or the like, and the circuit 21 is supported by a PCB substrate 22. The sensor unit 2 is connected to the circuit 21 and the PCB substrate 22. The PCB substrate 22 is mounted on a PCB substrate 15 via solder balls 16. In this configuration, there is a possibility that the solder balls 16, for example, could prevent reading of the product information. Similarly, there is a possibility that metal elements such as wiring or the like provided in the PCB substrates 15 and 22 could prevent reading of the product information. In the embodiment shown in FIGS. 8A and 8B, when the thickness of the electrical connection section and the metal elements in the Z direction is 40 μm or more, there is a high possibility that reading of the product information will become difficult, depending on the irradiation energy of the x-rays. The first product information part 6 is preferably provided at the position without overlapping with these kinds of electrical connection sections and metal elements when viewed from the Z direction.

### Fifth Embodiment

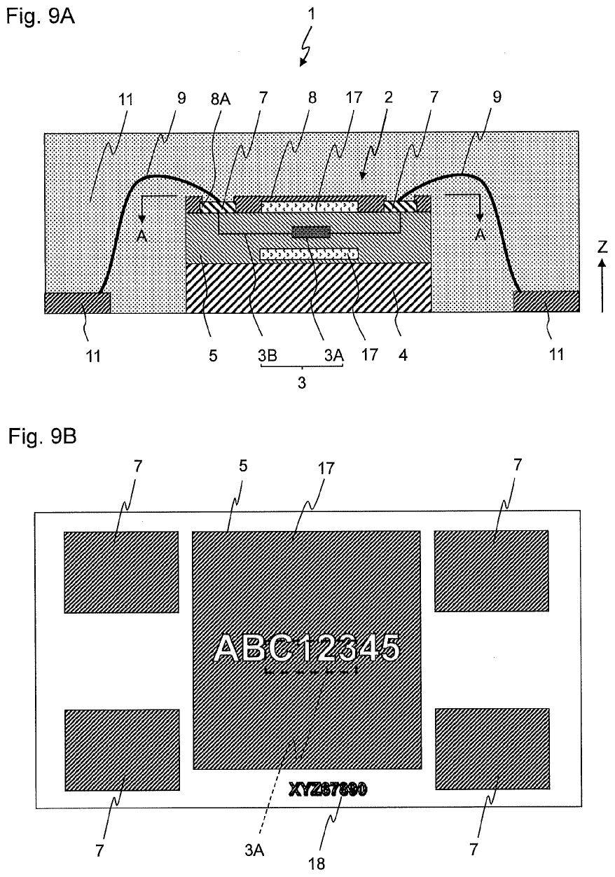

FIG. 9A shows a side cross-sectional view of the magnetic sensor 1 according to a fifth embodiment of the present invention. This embodiment is the same as the first embodiment except that the first product information part 6 doubles as a magnetic shield. A pair of magnetic shields 17 to shield an external magnetic field is provided on both sides of the magnetic field detection element 3A. FIG. 9B is a plan view along line A-A in FIG. 9A. The magnetic shield 17 is made of a soft magnetic material such as NiFe or the like, and the product information is formed on the soft magnetic material. The product information is formed by at least one of indentations, penetration holes or protrusions provided on the soft magnetic material. Supplementary identification information 18 used in the manufacturing process can also be provided in the vicinity of the magnetic shield 17. With this embodiment, a relatively large magnetic shield 17 is used as the first product information part 6, so largely displaying the identification information is possible, and visibility at the time of x-ray irradiation improves. Several preferred embodiments of the present invention were described in detail, but it is to be understood that various alterations and variations are possible without departing from the gist or scope of the attached claims.

1. An electronic device, comprising a function part, a first product information part made of metal, molded resin that covers the function part and the first product information part, and a barrier layer interposed between the first product information part and the molded resin.

2. The electronic device according to claim 1, wherein the first product information part is positioned between the function part and the barrier layer.

3. The electronic device according to claim 2, further comprising a substrate above which the function part is provided and an electrode layer connected to the function part;
wherein the electrode layer and the first product information part are made of the same metal and are provided at positions equidistant from the substrate.

4. The electronic device according to claim 2, wherein the first product information part is thinner than the thickness of the electrode layer.

5. The electronic device according to claim 2, wherein the first product information part is thicker than the thickness of the electrode layer.

6. The electronic device according to claim 2, wherein the barrier layer is a passivation film.

7. The electronic device according to claim 6, wherein the film thickness of the passivation film is 0.5 μm or more.

8. The electronic device according to claim 2, further comprising a substrate above which the function part is provided, a second product information part provided between the substrate and the first product information part, and a second barrier layer for the second product information part, wherein the second barrier layer is an insulating film that covers the function part and the second product information part.

9. The electronic device according to claim 8, wherein the function part has a wiring layer, and the wiring layer and the second product information part are made of the same metal and are provided at positions equidistant from the substrate.

10. The electronic device according to claim 2, further comprising a substrate above which the function part is provided, a second product information part provided on the substrate, and a second barrier layer for the second product information part, wherein the second barrier layer is an insulating film that covers the function part and the second product information part.

11. The electronic device according to claim 1, wherein the barrier layer is an insulating film that covers the function part and the first product information part.

12. The electronic device according to claim 11, further comprising a substrate above which the function part is provided, wherein the function part includes a wiring layer, and the wiring layer and the first product information part are made of the same metal and are provided at positions equidistant from the substrate.

13. The electronic device according to claim 1, further comprising a substrate above which the function part is provided, wherein the first product information part is provided on the substrate, and the barrier layer is an insulating film that covers the function part and the first product information part.

14. The electronic device according to claim 1, wherein the first product information part includes a three-dimensional pattern displaying at least one of characters, symbols and figures.

15. The electronic device according to claim 1, further comprising a metal element other than the first product information part, wherein the first product information part is positioned without overlapping with the metal element when viewed from a direction orthogonal to an information formation surface of the first product information part.

16. The electronic device according to claim 15, wherein the thickness of the metal element in the direction orthogonal to the information formation surface is 40 μm or more.

17. An electronic device assembly comprising the electronic device according to claim 1, and a PCB substrate above which the electronic device is mounted via an electrical connection part, wherein the first product information part is positioned without overlapping with a metal element of the PCB substrate and the electrical connection part when viewed from a direction orthogonal to an information formation surface of the first product information part.

18. The electronic device according to claim 1, wherein the first product information part doubles as a magnetic shield.

19. The electronic device according to claim 18, further comprising a soft magnetic material that includes the first product information part, wherein the soft magnetic material has product information formed with at least one of indentations, penetrating holes and projections.

20. The electronic device according to claim 1, wherein the function part includes a magnetoresistive effect element.

21. The electronic device according to claim 1, wherein the first product information part is made of Au or W.

22. A method of reading product information of an electronic device, the electronic device comprising a function part, a first product information part made of metal, a molded resin that covers the function part and the first product information part, and a barrier layer interposed between the first product information part and the molded resin, and the method includes irradiation of the electronic devices with x-rays from outside the molded resin and reading of the product information contained in the first product information part.
